(19) United States
(12) Patent Application Publication
(10) Pub. No.: US 2011/0001692 A1
(43) Pub. Date: Jan. 6, 2011

(54) INTEGRATED CIRCUITS FOR CONVERTING DIGITAL SIGNALS TO DIGITAL SIGNALS, LCD DRIVERS, SYSTEMS, AND OPERATING METHODS THEREOF

(75) Inventor: N. P. TU, Hsinchu (TW)

Correspondence Address: Lowe Hauptman Ham & Berner, LLP (TSMC), 1700 Diagonal Road, Suite 300, Alexandria, VA, 22314, US

(73) Assignee: TAIWAN SEMICONDUCTOR MANUFACTURING COMPANY, LTD., Hsinchu (TW)

(21) Appl. No.: 12/762,508

(22) Filed: Apr. 19, 2010

Related U.S. Application Data
(60) Provisional application No. 61/222,831, filed on Jul. 2, 2009.

(51) Int. Cl. G09G 3/36; H03M 1/66

(52) U.S. Cl. 345/98; 341/145

(57) ABSTRACT

An integrated circuit for converting digital signals to analog signals is provided. The integrated circuit includes a decoder coupled with at least one digital-to-analog converter (DAC). The decoder is capable of receiving at least one n-bit digital signal, decoding m bits of the at least one n-bit digital signal, and outputting at least one (n−m)-bit digital signal and at least one decoded digital signal. The at least one digital-to-analog converter (DAC) is capable of converting the at least one (n−m)-bit digital signal and the at least one decoded digital signal to at least one analog signal.

### CROSS-REFERENCE TO RELATED APPLICATIONS

The present application claims priority of U.S. Provisional Patent Application Ser. No. 61/222,831 filed on Jul. 2, 2009, which is incorporated herein by reference in its entirety.

### TECHNICAL FIELD

The present disclosure relates generally to the field of semiconductor circuits, and more particularly, to integrated circuits for converting digital signals to analog signals, LCD drivers, systems, and operating methods thereof.

### BACKGROUND

Applications for semiconductor devices may use power devices, such as a liquid crystal display (LCD) driver. An LCD driver can operate at a high voltage to drive pixels of the LCD and at a low voltage to operate associated logic circuits. The LCD display driver can output a plurality of signals through channels for driving dots or pixels of the LCD for achieving a desired color-resolution display and a desired image moving speed.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the numbers and dimensions of the various features may be arbitrarily increased or reduced for clarity of discussion.

FIG. 1 is a schematic drawing showing an exemplary integrated circuit including a decoder coupled with a digital-to-analog converter (DAC).

FIG. 2 is a schematic drawing illustrating an exemplary decoder.

FIG. 3 is a schematic drawing illustrating an exemplary DAC.

FIG. 4 is a schematic drawing illustrating an exemplary liquid crystal display (LCD) driver including an integrated circuit converting digital signals to analog signals.

FIG. 5 is a schematic drawing showing a system including an exemplary integrated circuit coupled with a means for receiving digital signals.

### DETAILED DESCRIPTION

For a conventional liquid crystal display (LCD) driver with 720 channels, the conventional LCD driver uses 720 digital-to-analog converters (DACs) for converting digital signals to analog signals. The DACs are disposed within a high voltage (HV) circuit region. In the HV circuit region, devices and/or transistors of the DACs have large sizes and dimensions for HV operations. The analog signals are output to dots of the LCD, displaying images carried by the digital signals. Each three of the dots of the LCD can be grouped as a pixel, including a red-light dot, a green-light dot, and a blue-light dot.

For providing a 10-bit resolution, each of the 720 DACs can receive a 10-bit digital signal D₀-D₉. Each of the 720 DACs can have 2¹⁰ or 1024 rows of 10-series switches. Each of the 10-series switches is controlled by one bit of the 10-bit digital signal D₀-D₉. As noted, the 720 DACs of the conventional LCD driver are disposed in a high voltage (HV) circuit region. The total number of the 10×1024 switches of each DAC will take a large percentage of the chip area of the LCD driver. If a bit-resolution of the DAC increases, the area of the DAC expands abnormally.

Based on the foregoing, integrated circuits that can convert analog to digital signals, systems, and operating methods thereof are desired.

It is understood that the following disclosure provides many different embodiments, or examples, for implementing different features of the disclosure. Specific examples of components and arrangements are described below to simplify the present disclosure. These are, of course, merely examples and are not intended to be limiting. In addition, the present disclosure may repeat reference numerals and/or letters in the various examples. This repetition is for the purpose of simplicity and clarity and does not in itself dictate a relationship between the various embodiments and/or configurations discussed. Moreover, the formation of a feature on, connected to, and/or coupled to another feature in the present disclosure that follows may include embodiments in which the features are formed in direct contact, and may also include embodiments in which additional features may be formed interposing the features, such that the features may not be in direct contact. In addition, spatially relative terms, for example, “lower,” “upper,” “horizontal,” “vertical,” “above,” “below,” “up,” “down,” “top,” “bottom,” etc. as well as derivatives thereof (e.g., “horizontally,” “downwardly,” “upwardly,” etc.) are used for ease of the present disclosure of one features relationship to another feature. The spatially relative terms are intended to cover different orientations of the device including the features.

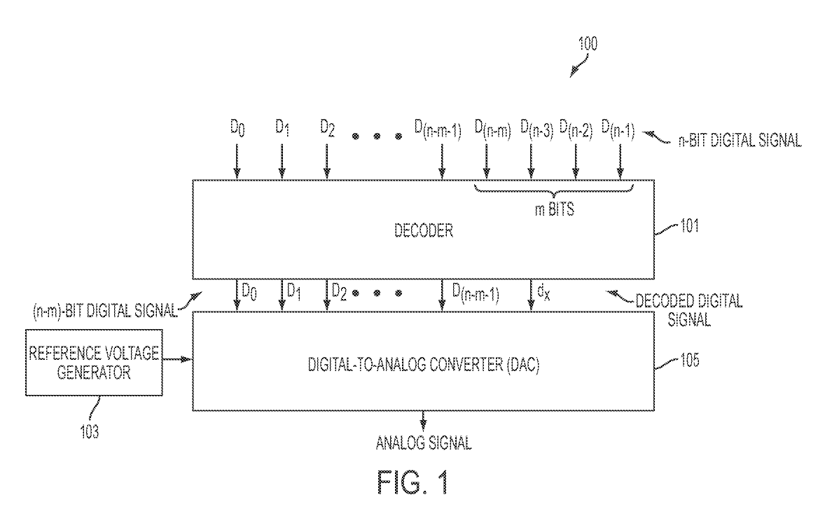

FIG. 1 is a schematic drawing showing an exemplary integrated circuit including a decoder coupled with a digital-to-analog converter (DAC). An integrated circuit 100 can include a driver, e.g., a liquid crystal display (LCD) driver, an LCD monitor drivers, an LCD display drivers, an LCD inverter, a super twist pneumatic (STN) driver, and/or other driver.

Referring to FIG. 1, the integrated circuit 100 can include a decoder 101 coupled with at least one DAC, e.g., DAC 105. In various embodiments, the decoder 101 can be directly or indirectly coupled with the DAC 105. The decoder 101 can receive at least one n-bit digital signal D₀-D₍ₙ₋₁₎. The decoder 101 can decode m bits, e.g., D₍ₙ₋ₘ₎-D₍ₙ₋₁₎, of the at least one n-bit digital signal D₀-D₍ₙ₋₁₎. The decoder 101 can output at least one (n−m)-bit digital signal, e.g., D₀-D₍ₙ₋₁₎, and at least one decoded digital signal, e.g., dₓ. The DAC 105 can receive and convert the at least one (n−m)-bit digital signal D₀-D₍ₙ₋ₘ₋₁₎ and the at least one decoded digital signal dₓ to at least one analog signal. In various embodiments, the “n” and “m” are integers and m is less than n. In other embodiments, “m” is an integer between about 3 and about 8.

In various embodiments using a 10-bit digital signal, the decoder 101 can decode, for example, 4 bits of the 10-bit digital signal. The decoder 101 can output a 6-bit digital signal and a decoded digital signal to the DAC 105. The DAC 105 can convert the 6-bit digital signal and the decoded digital signal to an analog signal. It is noted that the 10-bit of the digital signal and/or the 4 bits of the digital signals that are decoded described above are merely exemplary. The scope of the invention is not limited thereto.

In various embodiments, the m bits of the n-bit digital signal can be most significant bits (MSBs). The decoder 101 can be referred to as a MSB decoder. In other embodiments, the m bits of the n-bit digital signal can be least significant bits (LSBs). The decoder 101 can be referred to as a LSB decoder. In still other embodiments, the m bits can be randomly selected from the n-bit digital signal D₀-D₍ₙ₋₁₎.

In various embodiments, the integrated circuit 100 can include at least one reference voltage generator 103 coupled with the DAC 105. The reference voltage generator 103 can provide various voltage levels to the DAC 105 as reference voltages. In various embodiments using a 10-bit resolution DAC, the reference voltage generator 103 can provide 2¹⁰ or 1024 voltage levels. The (n−m)-bit digital signal D₀-D₍ₙ₋ₘ₋₁₎ and the decoded digital signal dₓ can control the DAC 105 to output one of the voltage levels provided by the reference voltage generator 103.

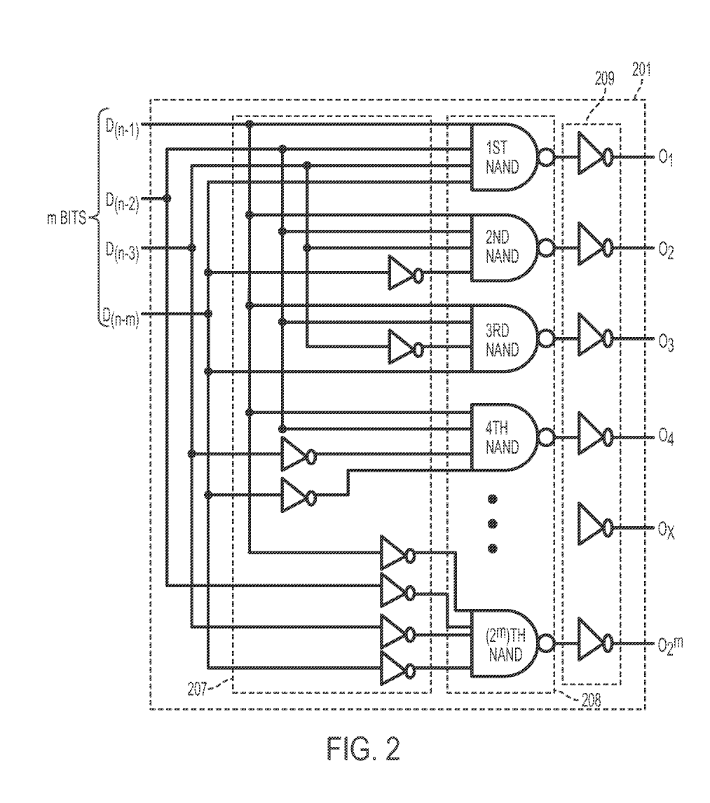

FIG. 2 is a schematic drawing illustrating an exemplary decoder. In FIG. 2, a decoder 201 can be similar to the decoder 101 described above in conjunction with FIG. 1. The decoder 201 can receive m bits, e.g., D₍ₙ₋ₘ₎-D₍ₙ₋₁₎, of the at least one n-bit digital signal D₀-D₍ₙ₋₁₎, decoding the m bits of the n-bit digital signal. Each of the input ends (not labeled) of the decoder 201 can receive one of the m bits D₍ₙ₋ₘ₎-D₍ₙ₋₁₎. The decoder 201 can include a plurality of inverters, e.g., (2^{m}−1) inverters 207. The decoder 201 can include a plurality of logic gates, e.g., 2^{m} NAND gates 208. Each of the (2^{m}−1) inverters 207 can be disposed between one of the input ends of the decoder 201 and one of the 2^{m} NAND gates 208. The decoder 201 can include a plurality of inverters, e.g., 2^{m} inverters 209. Each of the 2^{m} inverters 209 can be coupled with one of the 2^{m} NAND gates 208. Each of the 2^{m} inverters 209 can be coupled with one of output ends O₁ to O₂^{m} of the decoder 201.

It is noted that after decoding the m bits D₍ₙ₋ₘ₎-D₍ₙ₋₁₎ of the at least one n-bit digital signal D₀-D₍ₙ₋₁₎, each of the 2^{m} inverters 209 can output a high or low voltage state on its corresponding output ends O₁-O₂^{m}. The decoded digital signal dₓ can include all of the voltage states on the output ends O₁-O₂^{m} for representing the m bits D₍ₙ₋ₘ₎-D₍ₙ₋₁₎. The decoded digital signal dₓ and the (n−m)-bit digital signals D₀-D₍ₙ₋ₘ₋₁₎ described above in conjunction with FIG. 1 can be sent to a DAC. It is noted the decoder 201 described above in conjunction with FIG. 2 is merely exemplary. Any decoder that is capable of decoding several bits of n-bit digital signals can be used.

In various embodiments using a 10-bit digital signal D₀-D₉ and decoding 4 bits D₆-D₉ of the 10-bit digital signal D₀-D₉, the decoder 201 can include (2⁴−1) or 15 inverters 207. The decoder 201 can include 2⁴ or 16 NAND gates. The decoder 201 can include 2⁴ or 16 inverters 209. Each of the 16 inverters 209 can be coupled with one of output ends O₁-O₁₆. After decoding the 4 bits of the 10-bit digital signal, each of the 16 inverters 209 can output a high or low voltage state on its corresponding output ends O₁-O₁₆. For example, the voltage states on the output ends O₁-O₃ and O₅-O₁₆ are low and the voltage state on the output end O₄ is high. The decoded digital signal d₄ can include the voltage states “0001000000000000” on the output ends O₁-O₁₆ for representing the 4 bits D₆-D₉. The decoded digital signal d₄ and the undecoded 6-bit digital signals D₀-D₅ can be sent to a DAC.

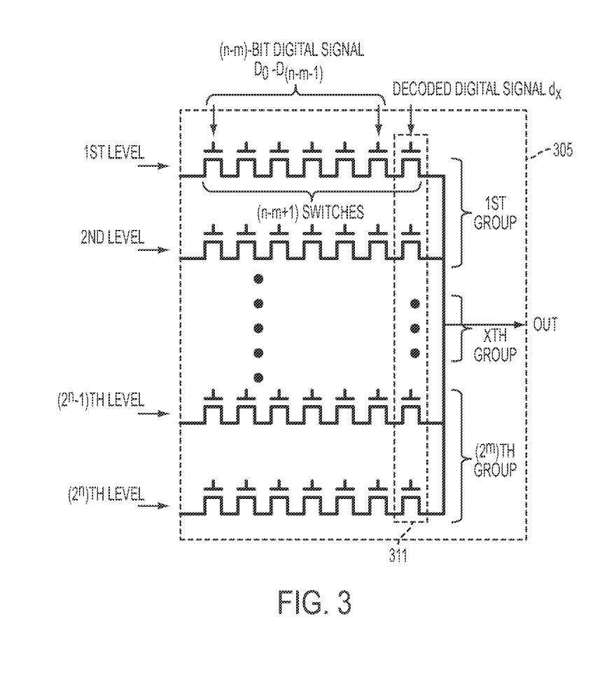

FIG. 3 is a schematic drawing illustrating an exemplary DAC. In FIG. 3, a DAC 305 can be similar to the DAC 105 described above in conjunction with FIG. 1. The DAC 305 can include a plurality of (n−m+1)-series switches, e.g., 2ⁿ rows of (n−m+1)-series switches. For providing an n-bit resolution, the DAC 305 can receive 2ⁿ voltage levels from a reference voltage generator (not shown). Each of the 2ⁿ voltage levels can be coupled with one of the 2ⁿ rows of (n−m+1)-series switches. The 2ⁿ rows of (n−m+1)-series switches can be disposed in parallel. Each of the 2ⁿ rows of (n−m+1)-series switches can include one of switches 311. The DAC 305 can receive the (n−m)-bit digital signals D₀-D₍ₙ₋ₘ₋₁₎ and the decoded digital signal dₓ from the decoder 201 described above in conjunction with FIG. 2.

In various embodiments, the 2ⁿ rows of (n−m+1)-series switches can be divided into 2^{m} groups, e.g., 1^{st} to (2^{m})^{th} groups. Each of the 2^{m} groups can include 2^{(n-m)} rows of (n−m+1)-series switches. The switches 331 of the 2^{(n-m)} rows of (n−m+1)-series switches of a single group can be coupled with one of the output ends O₁-O₂^{m} (shown in FIG. 2). The decoded digital signal dₓ output from the decoder 201 can control the switches 331 of the 2ⁿ rows of (n−m+1)-series switches of the 1^{st}-(2^{m})^{th} groups. It is noted the DAC 305 described above in conjunction with FIG. 3 is merely exemplary. The DAC 305 can be, for example, an oversampling DAC, an interpolating DAC, a Delta-Sigma DAC, an R-2R DAC, a thermometer coded DAC, a hybrid DAC, a segmented DAC, or any DAC that is capable of converting digital signals to analog signals can be used.

Referring again to FIG. 3, the (n−m)-bit digital signal D₀-D₍ₙ₋ₘ₋₁₎ can control (n−m) switches of each (n−m+1)-series switches. The decoded digital signal dₓ can control the switches 311 of each (n−m+1)-series switches. The (n−m)-bit digital signal D₀-D₍ₙ₋ₘ₋₁₎ and the decoded digital signal dₓ can control the switches of the DAC 305 such that one of the 2ⁿ voltage levels can be outputted as an analog signal.

In various embodiments using a 10-bit digital signal D₀-D₉ and decoding 4 bits D₆-D₉ of the 10-bit digital signal D₀-D₉, the DAC 305 can include 2¹⁰ or 1024 rows of 7-series switches. The 1024 rows of 7-series switches can be divided into 2⁴ or 16 groups. Each of the 16 groups can include 2⁶ or 64 rows of 7-series switches. The decoded digital signal d₄ output from the decoder 201 can control the switches 331 of the 1^{st}-16^{th} groups. For example, the decoded digital signal d₄ can have the “0001000000000000” voltage states on the output ends O₁-O₁₆. The low voltage states “0” of the decoded digital signal d₄ can turn off the switches 331 of the 1^{st}-3^{rd} and 5^{th}-16^{th} groups. The high voltage states “1” of the decoded digital signal d₄ can turn on the switches 331 of the 4^{th} group.

The 6-bit digital signal D₀-D₅ can control 6 switches of each 7-series switches. The decoded digital signal d₄ can turn on the switches 311 of the 4^{th} group. The 6-bit digital signal D₀-D₅ and the decoded digital signal dₓ can control the switches of the DAC 305 such that one of the 1024 voltage levels can be outputted as an analog signal. It is noted that the bit number of the 10-bit digital signal and/or the number of the m bits that are decoded described above are merely exemplary. For example, the “m” can be an integer number between about 3 and about 8. The scope of the invention is not limited thereto.

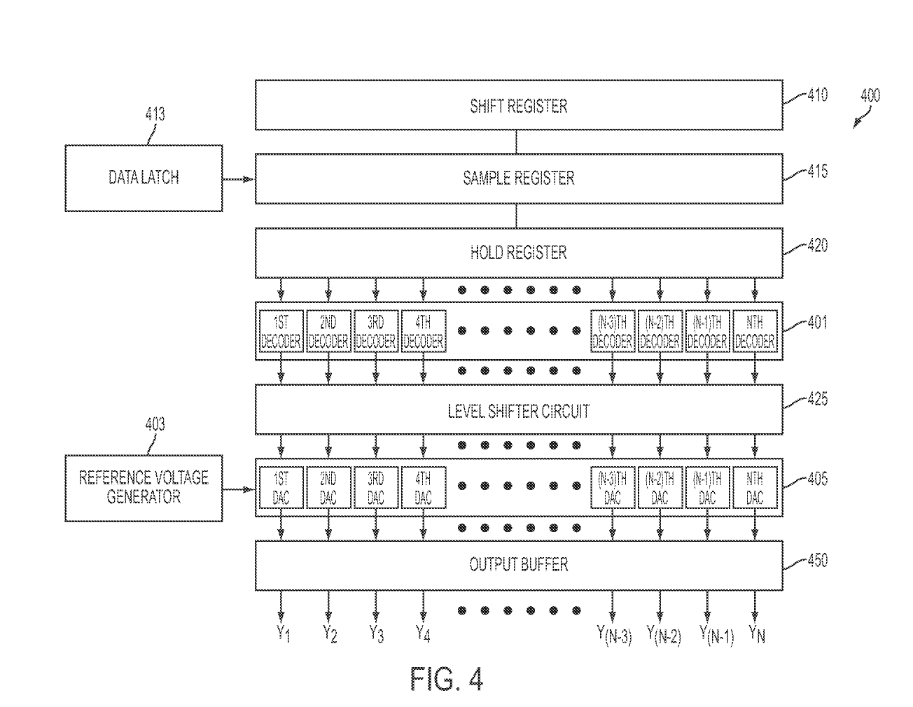

FIG. 4 is a schematic drawing illustrating an exemplary liquid crystal display (LCD) driver including an integrated circuit converting digital signals to analog signals. An LCD driver 400 can include a decoding circuit 401 including a plurality of decoders. For embodiments using a LCD driver with N channels, the decoding circuit 401 can have N decoders. Each of the N decoders can be similar to the decoder 101 described above in conjunction with FIG. 1. The LCD driver 400 can include a DAC circuit 405 including a plurality of DACs. For embodiments using a LCD driver with N channels, the DAC circuit 405 can have N DACs. Each of the N DACs can be similar to the DAC 105 described above in conjunction with FIG. 1. In various embodiments, the DAC circuit 105 can include at least one N-channel DAC (NDAC) and at least one P-channel DAC (PDAC).

Referring again to FIG. 4, the LCD driver 400 can include a level shift circuit 425 disposed between the decoding circuit 401 and the DAC circuit 405. The level shift circuit 425 can shift voltage levels of the (n−m)-bit digital signals and the decoded digital signal from the decoding circuit 401. For example, the voltage levels of the digital signals from the decoding circuit 401 can be shifted from low voltage levels to high voltage levels. The level shift circuit 425 can include a plurality of level shifters. In various embodiments, the level shift circuit 425 can include (n−m+1) level shifters corresponding to the bit number of the (n−m)-bit digital signal and the decoded digital signal.

In various embodiments, the LCD driver 400 can include a reference voltage generator 403, a shift register 410, a data latch 413, a sample register 415, a hold register 420, and an output buffer 450. The reference voltage generator 403 can be coupled with the DAC circuit 405. The data latch 413 can be coupled with the sample register 415. The shift register 410 can be configured to shift start pulses of input signals (not shown). The sample register 415 can be configured to sample the shifted signals from the shift register 410. The hold register 420 can be configured to hold the sampled signals from the sample register 415. Each of the decoders of the decoding circuit 401 can decode m bits of each n-bit digital signal from the hold register 420, outputting a (n−m)-bit digital signal and an decoded digital signal to the level shift circuit 425. The level shift circuit 425 can shift the voltage levels of the (n−m)-bit digital signals and the decoded digital signals, outputting voltage level-shifted (n−m)-bit digital signals and decoded digital signals to the DAC circuit 405. Each DAC of the DAC circuit 405 can convert the voltage level-shifted (n−m)-bit digital signals and decoded digital signals to analog signals. The output buffer 450 can receive the analog signals, outputting signals driving dots and/or pixels of the LCD.

As noted, the conventional LCD driver having 720 channels uses 720 DACs for converting digital signals to analog signals. Each of the 720 conventional DACs has 2¹⁰ 10-series switches for receiving 10-bit digital signals for providing a 10-bit resolution. Since the 720 conventional DACs are disposed in a HV circuit region, the 720 conventional DACs will consume a large percentage chip area of the conventional LCD driver.

In contrary to the conventional LCD driver, the LCD driver 400 can use the decoding circuit 401 for decoding m bits, e.g., 4 bits, of each n-bit, e.g., 10-bit, digital signal, outputting a 6-bit digital signal and an decoded digital signal. Each DAC of the DAC circuit 405 then can use 2¹⁰ rows of 7-serial switches for converting the 6-bit digital signals and the decoded digital signals to analog signals. Compared with the conventional DAC having 10-series switches, each DAC of the DAC circuit 405 can use 7-series switches. The number of the switches in series has been reduced. The impedance and/or resistance of the switches in series can be desirably reduced. From the foregoing, noises to the DAC circuit 405 can be desirably reduced.

It is also found that each DAC of the DAC circuit 405 can merely use 2¹⁰ rows of 7-serial switches for converting digital signals to analog signals. Compared with the conventional DAC using 2¹⁰ rows of 10-series switches, the number of the switches of each DAC of the DAC circuit 405 can be substantially reduced by 3×2¹⁰ or 3072 switches. The area percentage of the DAC circuit 405 to the LCD driver 400 can be desirably reduced. In various embodiments, the area of the DAC circuit 405 can be reduced by about 30% compared with the area of the 720 conventional DACs.

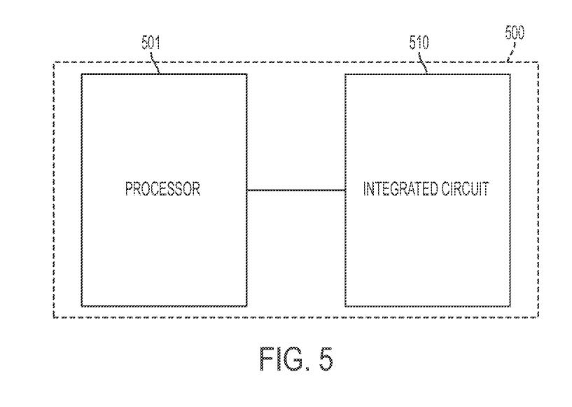

FIG. 5 is a schematic drawing showing a system including an exemplary integrated circuit coupled with a means for receiving digital signals. In FIG. 5, a system 500 can include a processor 501 coupled with an integrated circuit 510. The processor 501 is capable of controlling the integrated circuit 510. In various embodiments, the processor 501 can be a processing unit, central processing unit, digital signal processor, or other suitable processor. The integrated circuit 510 can be similar to the integrated circuit 100 described above in conjunction with FIG. 1 or the LCD driver 400 described above in conjunction with FIG. 4.

In various embodiments, the system 500 can include a high definition television, a vehicle, a cell phone, a set top box, a media player, a personal computer (PC), a laptop, a notebook, a personal digital assistant (PDA), a calculator, and/or any system.

In various embodiments, the processor 501 and the integrated circuit 510 can be physically and electrically coupled with a printed wiring board or printed circuit board (PCB) to form an electronic assembly. The electronic assembly can be part of an electronic system such as computers, wireless communication devices, computer-related peripherals, entertainment devices, or the like.

In various embodiments, the system 500 including the integrated circuit 510 can provides an entire system in one IC, so-called system on a chip (SOC) or system on integrated circuit (SOIC) devices. These SOC devices may provide, for example, all of the circuitry needed to implement a cell phone, personal data assistant (PDA), digital VCR, digital camcorder, digital camera, MP3 player, or the like in a single integrated circuit.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An integrated circuit for converting digital signals to analog signals, the integrated circuit comprising:
a decoder, the decoder being capable of:
receiving at least one n-bit digital signal;
decoding m bits of the at least one n-bit digital signal; and
outputting at least one (n−m)-bit digital signal and at least one decoded digital signal; and
at least one digital-to-analog converter (DAC) coupled with the decoder, the at least one DAC being capable of converting the at least one (n−m)-bit digital signal and the at least one decoded digital signal to at least one analog signal.

2. The integrated circuit of claim 1, wherein the decoder is a most significant bit (MSB) decoder.

3. The integrated circuit of claim 1 further comprising a level shifter disposed between the decoder and the at least one DAC, wherein the level shifter is capable of shifting voltage levels of the at least one (n−m)-bit digital signal and the at least one decoded digital signal.

4. The integrated circuit of claim 3, wherein the decoder is disposed in a low voltage (LV) circuit region and the at least one DAC is disposed in a high voltage (HV) circuit region.

5. The integrated circuit of claim 1, wherein the at least one DAC comprises 2ⁿ×(n−m+1) switches.

6. The integrated circuit of claim 1, wherein the at least one DAC comprises 2ⁿ rows of (n−m+1)-series switches and the 2ⁿ rows of (n−m+1)-series switches are disposed in parallel.

7. The integrated circuit of claim 1, wherein m is an integer between about 3 and about 8.

8. A liquid crystal display (LCD) driver having N channels comprising:
N decoders, each of the N decoders being capable of:
receiving at least one n-bit digital signal;
decoding m bits of the at least one n-bit digital signal; and
outputting at least one (n−m)-bit digital signal and at least one decoded digital signal;
a level shift circuit coupled with the N decoders; and
N digital-to-analog converters (DACs) coupled with the level shift circuit, each of the N DACs being capable of converting the at least one (n−m)-bit digital signal and the at least one decoded digital signal to at least one analog signal.

9. The LCD driver of claim 8, wherein each of the N decoders is a most significant bit (MSB) decoder.

10. The LCD driver of claim 8, wherein the N decoders are disposed in a low voltage (LV) circuit region and the N DACs are disposed in a high voltage (HV) circuit region.

11. The LCD driver of claim 8, wherein each of the N DACs comprises 2ⁿ×(n−m+1) switches.

12. The LCD driver of claim 8, wherein each of the N DACs comprises 2ⁿ rows of (n−m+1)-series switches and the 2ⁿ rows of (n−m+1)-series switches are disposed in parallel.

13. The LCD driver of claim 8 further comprising:
a shift register;
a sample register coupled with the shift register;
a hold register coupled with the sample register and the N decoders; and
an output buffer coupled with the N DACs.

14. The LCD driver of claim 8, wherein m is an integer between about 3 and about 8.

15. The LCD driver of claim 8, wherein the level shifter comprises (n−m+1) level shifters.

16. A method for converting digital signals to analog signals, the method comprising:
decoding m bits of at least one n-bit digital signal for providing at least one (n−m)-bit digital signal and at least one decoded digital signal; and
converting the at least one (n−m)-bit digital signal and the at least one decoded digital signal to at least one analog signal.

17. The method of claim 16 further comprising:
shifting voltage levels of the at least one (n−m)-bit digital signal and the at least one decoded digital signal before converting the at least one (n−m)-bit digital signal and the at least one decoded digital signal to the at least one analog signal.

18. The method of claim 16, wherein decoding m bits of the at least one n-bit digital signal comprises decoding m most significant bits (MSBs) of the at least one n-bit digital signal.

19. The method of claim 16, wherein m is an integer between about 3 and about 8.
